(19) United States
(12) Patent Application Publication
(10) Pub. No.: US 2010/0264998 A1
(43) Pub. Date: Oct. 21, 2010

(54) APPARATUS AND METHOD FOR CHARGE TRANSFER

(75) Inventors: Daniel Koenig, Munich (DE); Joerg Kotthaus, Graefelfing (DE)

Correspondence Address: DICKSTEIN SHAPIRO LLP, 1633 Broadway, NEW YORK, NY, 10019, US

(73) Assignee: LUDWIG-MAXIMILIANS-UNIVERSITAET MUENCHE, Munich (DE)

(21) Appl. No.: 12/669,760

(22) PCT Filed: Jul. 16, 2008
(86) PCT No.: PCT/EP2008/005812

§ 371 Date: Jan. 19, 2010

(30) Foreign Application Priority Data
Jul. 20, 2008 (DE) 10 2007 034 072.0

(51) Int. Cl. H03B 5/30; H03B 5/32

(52) U.S. Cl. 331/155

(57) ABSTRACT

The invention relates to an apparatus and a method for charge transfer, wherein a charge transfer apparatus (10) in particular comprises: an oscillation generator (20) for production of acoustic oscillations; at least two mutually separated electrode elements (16a, 16h); and a mechanical resonator element (12), which is coupled to the oscillation generator and has at least one charge transfer section (18) which can be moved between the two electrode elements (16a, 16b).

The invention relates to an electric charge transfer on the basis of a micro or nanomechanical system. Specifically, the invention relates to an apparatus and a method for high-precision generation and detection of small currents and potential changes or charge changes.

The generation and determination of very small electric currents and potential changes place very high demands on the necessary measuring devices and generators. Nowadays, very low-noise semiconductor components are mostly used for this. On the other hand, for example very small currents (e.g. 100 pA with a relative velocity of up to 10⁻⁵) are generated at the Physikalisch-Technische Bundenanstalt (federal institute of physics and metrology) with a ramp generator for voltages (dU/dt) and an air condenser with the capacity C using the relationship I=C*dU/dt.

It is the object of the present invention to provide an apparatus and a method for precisely detecting and/or controlling the transfer of an electric charge. This object is solved by an apparatus and a method having the features indicated in the independent claims. Preferred embodiments are subject of the dependent claims.

Thus, the present invention in particular provides a charge transfer apparatus for transferring electric charges, comprising:

an oscillation generator for generating acoustic oscillations, or an acoustic oscillation generator or generator;
at least two electrode elements spaced from each other, which are particularly formed as electrically conductive contact elements, in particular as electrical leads; and
a mechanical resonator element directly or indirectly coupled to the oscillation generator and having at least one charge transfer portion movable between the two electrode elements, said charge transfer portion being particularly designed to absorb and deliver an electric charge.

Thereby, an electric charge can be transferred between the two electrode elements in a particularly well-controllable and definable manner. In particular, due to the distance between the two electrode elements, a direct current flow is prevented. The transfer of the electric charge between the two electrode elements can take place by means of the charge transfer portion of the resonator element.

Preferably, the charge transfer portion is arranged on an oscillating portion of the resonator element and is fixedly connected therewith. The resonator element can be excited to perform mechanical oscillations particularly in its oscillating portion such that the charge transfer portion can be moved in an oscillating manner or is moved by the oscillations or due to the oscillations between the two electrode elements. Preferably, the charge transfer portion can be moved substantially periodically from one electrode element to the other and back. In particular, the charge transfer portion can be moved to the individual electrode elements such that a charge transfer between the respective electrode element and the charge transfer portion is made possible. Preferably, an ohmic contact and/or a tunneling contact can be formed between the respective electrode element and the charge transfer portion.

In this case, acoustic oscillations do in particular not only mean sound waves in the audio frequency range. Instead, an acoustic oscillation is preferably understood to be any mechanical, preferably substantially non-polar oscillation of a medium. In particular in solid objects as a medium, these acoustic oscillations also comprise transversal, preferably non-polar oscillations in addition to longitudinal oscillations. In particular, an acoustic oscillation might comprise one or more longitudinal and/or transversal oscillations. Depending on the medium and the oscillation frequency, a wavelength of an acoustic oscillation might as well be greater than the spatial extension of the medium, such as a carrier substrate. In this case, the acoustic oscillation represents for example an in-phase movement of the entire medium, similar to shaking.

Preferably, the at least one resonator element has at least a resonance frequency in the range between 10 kHz and 1 THz, preferably in the range greater than 0.1 MHz and/or smaller than 1 GHz, particularly preferably in a range of more than 1 MHz and/or less than 100 MHz. In other embodiments, frequencies are used that are below 10 kHz or above 1 THz. Preferably, the oscillation generator is designed to generate acoustic oscillations in the corresponding frequency range.

Preferably, the charge transfer portion comprises an electrically conductive, in particular metallic island arranged on an at least partly electrically insulating oscillating portion of the resonator element.

Particularly preferably, the oscillation generator comprises a piezo actuator. In this case, the acoustic oscillation is thus preferably excited by an electric signal or alternating field. In another preferred embodiment, the oscillation generator comprises a medium that thermally extends by absorption of a laser pulse.

Preferably, the charge transfer apparatus comprises a carrier substrate via which the resonator element couples mechanically to the oscillation generator for transferring acoustic oscillations from the oscillation generator to the resonator element. The resonator element is preferably arranged on and/or fixed to the carrier substrate via a first end portion and a second end portion and is tensile stressed at least in an oscillating portion arranged between the two end portions and preferably spaced from the carrier substrate. The oscillating portion is preferably formed like a string or a beam or a land.

In another preferred embodiment, the resonator element is only arranged on and/or fixed to the carrier substrate via a first end portion. A second end portion is preferably movable between the two electrode elements when the resonator element is elastically deformed, wherein the charge transfer portion is arranged on the second end portion. Thus, in particular the second end portion forms the oscillating portion of the resonator element in this embodiment.

Preferably, the charge transfer apparatus comprises a shielding housing for shielding electric fields and/or magnetic fields, in particular electromagnetic fields, wherein the resonator element 12 is arranged within or at least partly within the shielding housing. Particularly preferably, the oscillation generator, in particular the piezo actuator, is arranged external or at least partly external to the shielding housing. Thereby, a coupling of electromagnetic oscillations, which may occur in the generation of the acoustic oscillations, in the process of a charge transfer is prevented or at least reduced by the charge transfer portion.

In a preferred embodiment, the charge transfer apparatus comprises a sensor electrode capacitively coupled to the charge transfer portion. Depending on the application, the sensor electrode serves for example as a gate electrode, by means of which the potential of the charge transfer portion and thus a current flow through the electrode elements is changed or controlled similar to a field effect transistor or a single electron transistor, when the electrical potential on the sensor electrode changes. In this connection, the charge transfer apparatus functions preferably as a charge or potential sensor and/or as a controllable current source. In another application, a change of the electrical potential of the charge transfer portion is preferably detected via the sensor electrode. In this application, the charge transfer apparatus functions preferably as a current counter or electron counter in particular for precise current calibration.

Preferably, the charge transfer apparatus comprises a single electron transistor with a Coulomb blockade island, which is capacitively coupled to the sensor electrode, and contact electrodes coupling to the Coulomb blockade island via tunneling contacts.

Preferably, the charge transfer apparatus comprises a plurality of resonance cells arranged on the carrier substrate, each resonance cell comprising:

at least one first electrode element and one second electrode element spaced from the first one; and
at least one mechanical resonator element coupled to the oscillation generator and having at least one charge transfer portion movable between the respective electrode elements.

Preferably, the first electrode elements of the plurality of resonance cells are connected to each other in an electrically conductive manner. Alternatively or in addition, preferably the second electrode elements of the plurality of resonance cells are connected to each other in an electrically conductive manner. In a preferred embodiment, a resonance cell or a plurality of resonance cells has/have a sensor electrode.

In a preferred embodiment, a plurality of the resonator elements of the plurality of resonance cells has different resonance frequencies. This can be achieved e.g. by a different length and/or thickness of the oscillating portion and/or by different tensile stresses and/or by forming tuning elements, which influence the inertial mass of the oscillating portion with their masses. Alternatively or in addition, a plurality of the resonator elements of the plurality of resonance cells preferably has the same resonance frequency.

Furthermore, the invention provides a method for transporting an electric charge, comprising:

applying an electrical voltage between two mutually spaced electrode elements; mechanically exciting at least one resonator element by means of acoustic oscillations such that a charge transfer portion comprised by the resonance element contacts the two electrode elements with at least one resonance frequency of the resonator element alternately in an electrical manner.

Here, upon each contact of the charge transfer portion with an electrode element, the electrical potential of the charge transfer portion is matched to the electrical potential of the respective electrode element or is at least approximated, which involves a charge transfer in each case. Thus, the charge transfer depends on the applied voltage and the resonance frequency. In particular, in the case of a very small charge transfer portion together with low temperatures, a fixed quantization of the charge transfer occurs due to the Coulomb blockade, which leads to voltage regions in which the voltage has only very little influence or almost no influence on the charge transfer. In these voltage regions, a particularly precisely determined current flow is obtained thereby, which may preferably be used as a current normal or current standard.

Preferably, the resonator element is arranged on a carrier substrate, and the acoustic oscillations used to excite the resonator element are formed in the carrier substrate and/or are transmitted to the resonator element by the carrier substrate. Particularly preferably, the acoustic oscillations are not generated directly in the carrier substrate and most of all not directly on the resonator element. By a remote generation and a transmission of the acoustic oscillations, an improved decoupling of the charge transfer from disturbances caused by the generation of the acoustic oscillations can be achieved. Preferably, mechanically exciting comprises generating an acoustic oscillation by means of a piezo actuator.

Thus, in a preferred application, an inventive apparatus is used as a current source or current normal or current standard by particularly preferably employing a method according to the present invention or a preferred embodiment thereof. In particular, such a use comprises preferably applying a direct voltage to the electrode elements such that an integer number of electrons, in particular defined by the Coulomb blockade, in particular one electron per oscillation period of the resonator element, is transferred from one electrode element to the other electrode element.

In another preferred embodiment, the method comprises:

capacitively coupling a sensor electrode to the charge transfer portion; and
detecting an electric current and/or a current change by the electrode elements.

Thus, an inventive apparatus is preferably used as a potential sensor or charge sensor by particularly preferably employing a method according to the present invention or a preferred embodiment thereof. In particular, such a use comprises preferably applying a direct voltage to the electrode elements such that on a time average, a half-integer number of electrons, in particular half an electron or 1.5 electrons per oscillation period of the resonator element, is transferred from one electrode element to the other electrode element. That is, on a time average, an electron is transferred e.g. only in every second oscillation period, or on average, an odd number of electrons is transferred in two consecutive oscillation periods together.

In a further preferred embodiment, the method comprises:

capacitively coupling a sensor electrode to the charge transfer portion; and
detecting an electrical potential and/or a potential change of the charge transfer portion by detecting an electrical potential or a potential change of the sensor electrode.

Particularly preferably, detecting the electrical potential or the potential change of the sensor electrode comprises detecting an electrical conductivity or an electric current of a single electron transistor capacitively coupled to the sensor electrode. Thereby, the charge of the charge transfer portion with individual electrons during the charge transfer process can be detected in a time-resolved manner. Thus, an inventive apparatus is preferably used as an electron counter by particularly preferably employing a method according to the present invention or a preferred embodiment thereof.

In a further preferred embodiment, a charge transfer apparatus is used for particularly low-noise measurements or as a particularly low-noise current source or electron counter, by at least one or more electrode elements and/or one or more charge transfer portions and/or one or more sensor electrodes and/or one or more contact electrodes of the single electron transistor and/or one or more Coulomb blockade islands of the single electron transistor comprising superconducting material.

The invention will be exemplarily described in the following on the basis of accompanying drawings of preferred embodiments, which show:

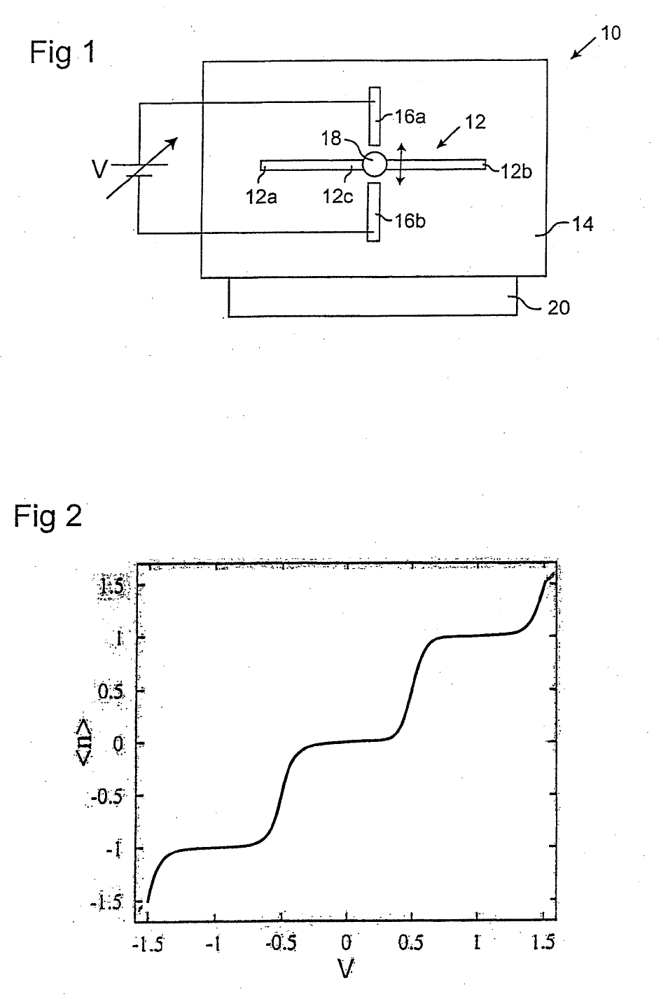

FIG. 1 a schematic top view of a charge transfer apparatus according to a first preferred embodiment of the invention;

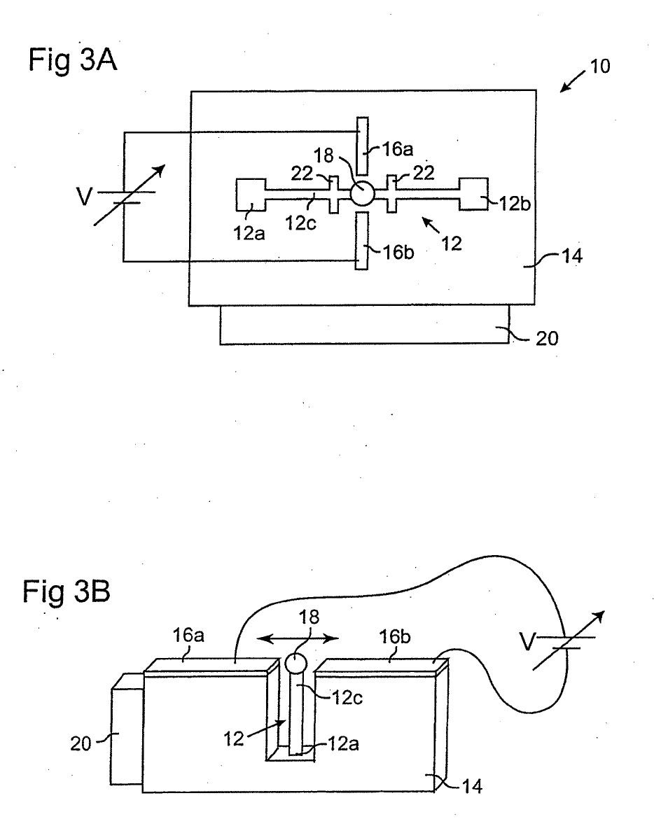

FIG. 2 a characteristic curve for a voltage-dependent charge transfer according to a preferred embodiment of the invention;

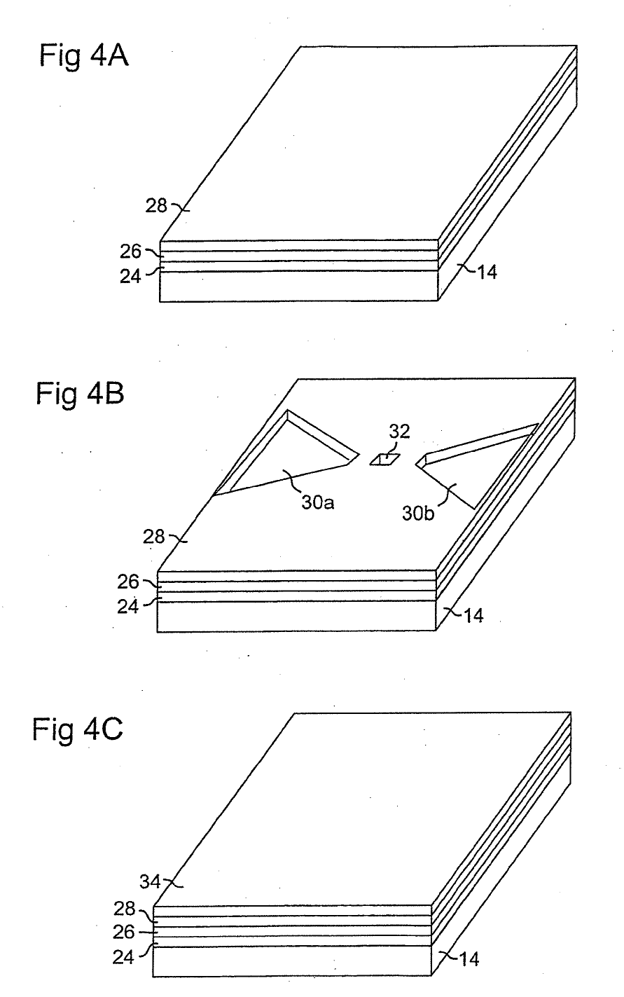

FIGS. 3A and 3B schematic illustrations of charge transfer apparatuses according to further preferred embodiments of the invention;

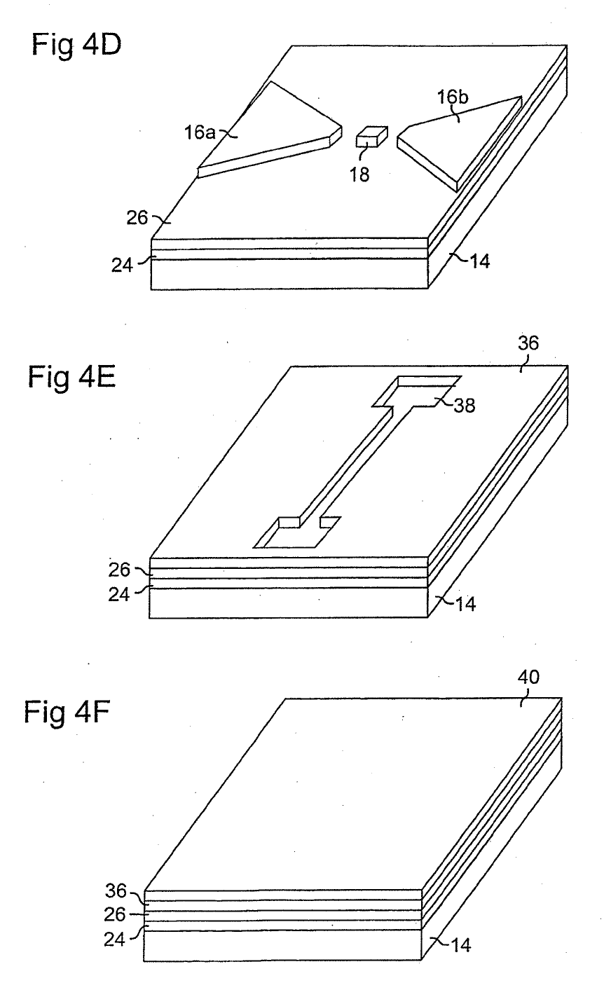

FIGS. 4A to 4J schematic illustrations of individual method steps of a production method for an apparatus according to a preferred embodiment of the invention;

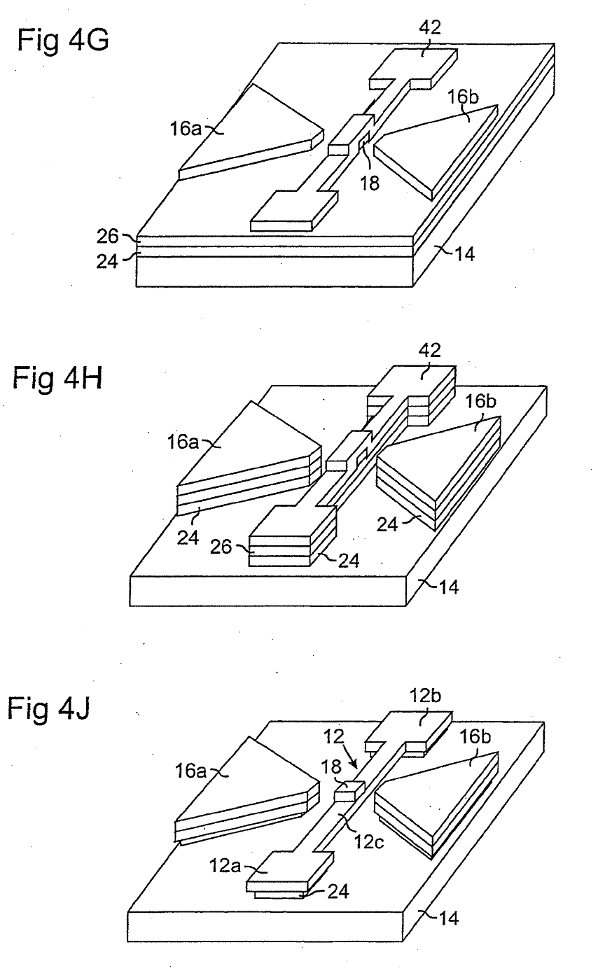

FIG. 5 a schematic illustration of a further apparatus having a shielding housing according to a further preferred embodiment;

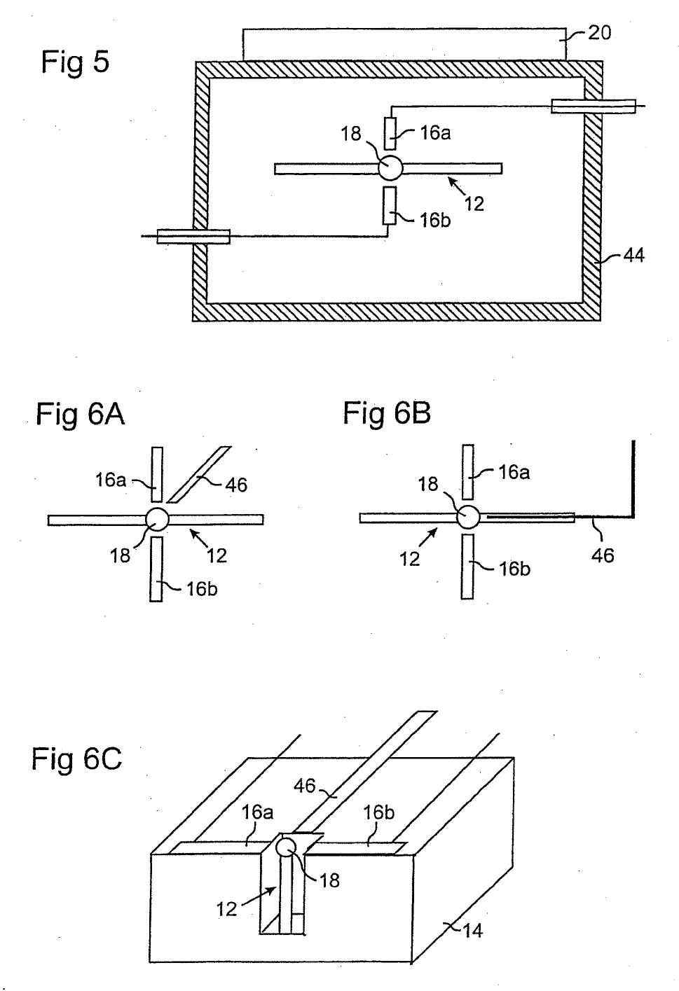

FIGS. 6A to 6C schematic illustrations of the arrangement of an additional gate electrode in an apparatus according to further preferred embodiments;

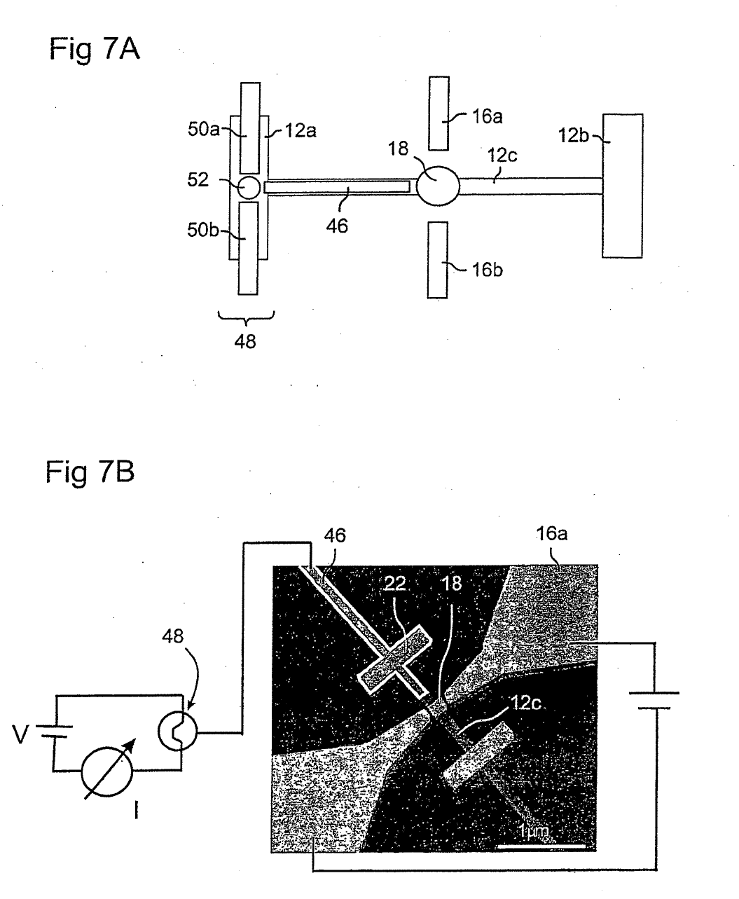

FIG. 7A a schematic illustration for explaining a charge transfer apparatus for counting individual electrons according to a further preferred embodiment;

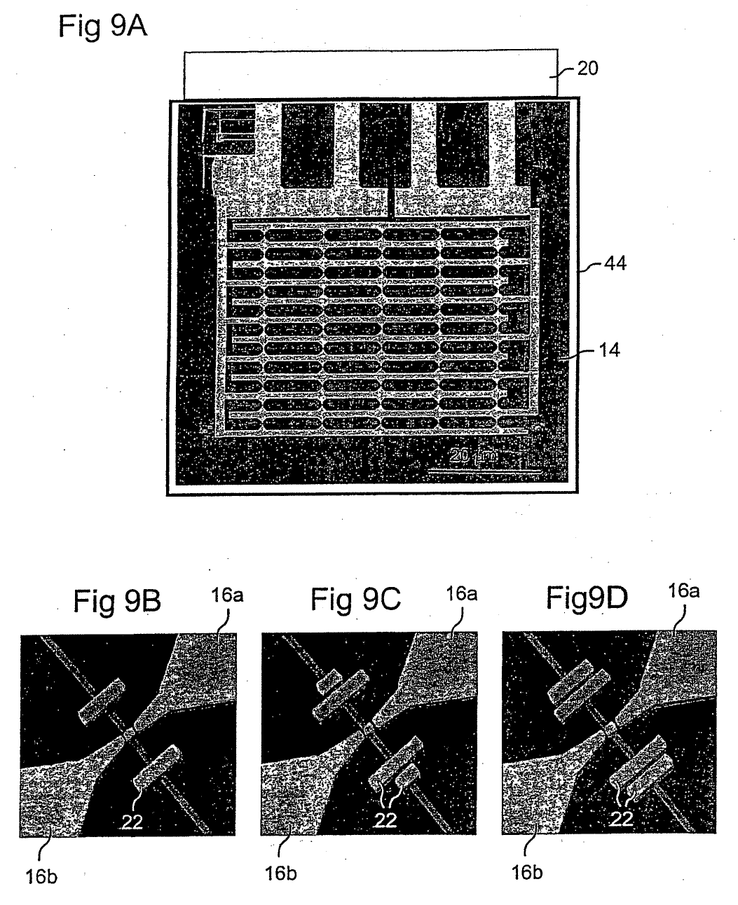

FIG. 7B an electron microscope (REM) picture of a resonator element of an apparatus according to FIG. 9A together with a schematic illustration of a preferred electrical connection;

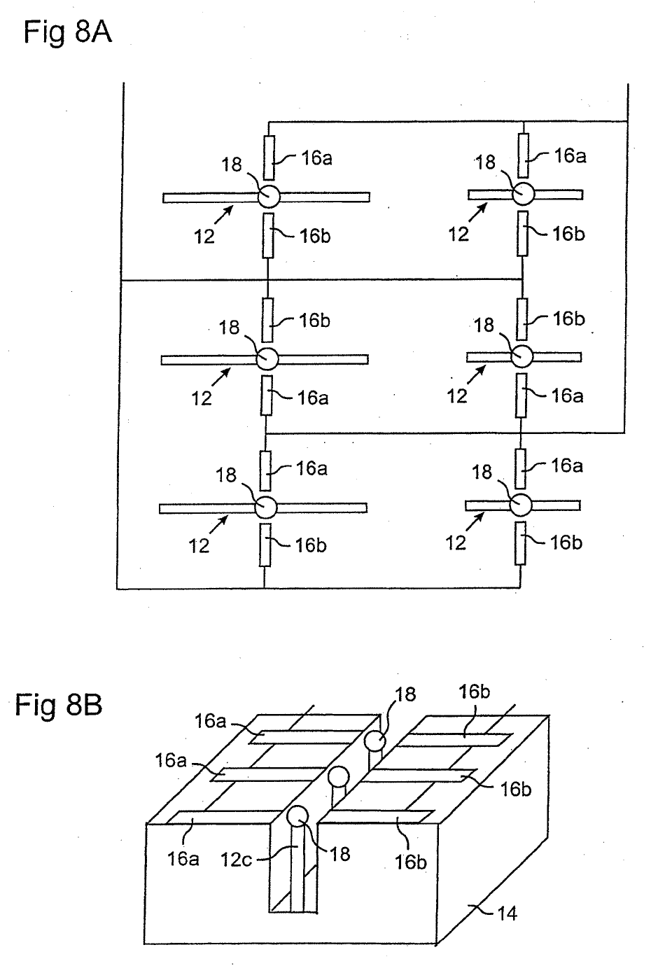

FIGS. 8A and 8B schematic illustrations of arrangements with a plurality of resonator elements in apparatuses according to preferred embodiments; and

FIGS. 9A to 9D REM pictures of resonator elements of an apparatus according to a preferred embodiment of the invention.

FIG. 1 shows a schematic top view of a charge transfer apparatus 10 according to a first preferred embodiment of the invention. The charge transfer apparatus 10 comprises a resonator element 12 extending substantially along a longitudinal direction from a first end portion 12a to a second end portion 12b of the resonator element 12. Preferably, the resonator element is formed as an elongated structure in the form of a string or a beam or a land. In the embodiment shown in FIG. 1, the resonator element 12 is directly or indirectly tightly connected with the carrier substrate 14 via its end portions 12a, 12b or at its end portions 12a, 12b. The carrier substrate 14 preferably has a substrate normal direction being perpendicular to the projection plane in the illustration of FIG. 1. In the first preferred embodiment, the longitudinal direction of the resonator element 12 is substantially perpendicular to the substrate normal direction, i.e. the resonator element 12 extends substantially parallel to a substrate plane. A direct connection of the resonator element 12 to the carrier substrate 14 could be achieved by directly arranging the end portions 12a and 12b on the carrier substrate 14, while for an indirect connection for example an intermediate layer, such as a later-described sacrificial layer, may be arranged between the end portions 12a or 12b and the carrier substrate 14.

Between the two fixed end portions 12a, 12b the resonator element 12 comprises an oscillating portion 12c which is movable relative to the carrier substrate 14 and can oscillate in particular about a rest position. In the shown embodiment, the oscillating portion 12c is formed as the middle portion of the resonator element 12. Preferably, the oscillating portion 12c is spaced from the carrier substrate 14, which allows the oscillating portion 12c to oscillate freely. Preferably, the resonator element 12 comprises a resonator carrier layer that is tensile stressed in the longitudinal direction. Thereby, a proper resilient force on the oscillating portion 12c for an oscillation about the rest position is achieved. The forces of the tensile stress in the form of a tensioned string are transferred to the carrier substrate 14 via the end portions 12a, 12b or are exerted by the carrier substrate 14. Depending on the stress and elasticity of the resonator element 12, the resonator element 12 has at least one resonance frequency for oscillations about the rest position.

Moreover, the charge transfer apparatus 10 comprises a first electrode element 16a and a second electrode element 16b, which are spaced from each other. The oscillating portion 12c is arranged at least partly between the two electrode elements 16a, 16b. As is shown in FIG. 1, the resonator element 12 and in particular its oscillating portion 12c comprises a charge transfer portion 18, which is arranged substantially between the two electrode elements and which can move between the two electrode elements 16 together with the oscillating portion 12c upon oscillation excitation of the resonator element 12. The charge transfer portion 18 is in particular suitable for absorbing an electric charge. To this end, the charge transfer portion comprises an electrically conductive material, e.g. metal, in a preferred embodiment. For example, the charge transfer portion 18 is formed by a gold island. Other materials, in particular metals, may be employed here as well. In another preferred embodiment, the charge transfer portion comprises an electrically insulating material with at least one electronic level as charge-trapping level, i.e. in particular a discrete energy level for an electron. Preferably, the charge transfer portion 18 is arranged on an electrically insulating region of the oscillating portion 12c in order to prevent or reduce the leakage of electric charge from the charge transfer portion 18 via the rest of the resonator element.

Preferably, the charge transfer portion 18 connected with the oscillating portion 12c can oscillate substantially periodically in the distance direction between the two electrode elements 16. If the amplitude of this oscillation is sufficiently large, the charge transfer portion 18 contacts the first electrode element 16a and the second electrode element 16b alternately and preferably periodically in an electrical manner. As the electrical contact, an ohmic contact and/or a tunneling contact between the charge transfer portion 18 and the respective electrode element 16 is formed preferably for a short time.

The resonator element 12 can be excited to perform an oscillation in particular by an oscillation generator 20, which is arranged on the carrier substrate 14 in the shown embodiment. To this end, the oscillation generator 20 is designed to generate acoustic oscillations that are transferred to the resonator element 12 via the carrier substrate 14. As the acoustic oscillations, mechanical, preferably non-polar oscillations, are transferred to the resonator element 12. In another preferred embodiment, the oscillation generator is arranged directly on the resonator element.

Preferably, the oscillation generator 20 comprises a piezo actuator operated via a voltage signal or an alternating voltage and therewith transfers acoustic oscillations to the carrier substrate 14. Depending on the voltage signal or the alternating voltage, the generated acoustic oscillations comprise at least one frequency component. They may as well comprise a plurality of frequency components or a continuum of frequency components. In particular, if the acoustic oscillations generated by the oscillation generator 20 comprise the at least one resonance frequency of the resonator element 12, the resonator element 12 is particularly efficiently excited to perform a mechanical oscillation.

As the oscillation generator, a different generator for mechanical oscillations might be provided as well. For example, in a further preferred embodiment, a substrate might be provided as the oscillation generator 20, which substrate generates mechanical oscillations by thermal expansion thereof. In particular, this substrate might be excited to perform thermal expansions by absorption of a one-time or a periodically recurrent laser pulse or by a temporally intensity-modulated, continuous laser beam, and at the same time transfer mechanical oscillations to the resonator element 12.

Preferably, an electrical voltage, in particular a direct voltage V, is applied to the electrode elements 16a, 16b. Upon each contact between the charge transfer portion 18 and one of the electrode elements 16, an electric charge can be transferred from the electrode element 16 to the charge transfer portion 18 or vice versa, depending on the applied voltage V, for example by an ohmic current flow and/or by a quantum mechanical tunneling effect of the charge carriers. In addition to the applied voltage V, the transferred charge also depends on the electrical capacity of the charge transfer portion 18, which in turn particularly depends on the size of the charge transfer portion 18. In a preferred embodiment, the electrical capacity of the charge transfer portion 18 is so small that the energy distances, when charged with individual elementary charges e, i.e. the Coulomb blockades, are larger or at least not essentially smaller than the value of the average thermal energy k_{B}T of the electrons at an operating temperature T of the charge transfer apparatus, with the Boltzmann's constant k_{B}. Thus, by specifying the applied voltage V, the number of elementary charges (electrons) transferred between the charge transfer portion 18 and one electrode element 16 per contact process can be adjusted. In particular, the number of electrons transferred from one electrode element 16a to the other electrode element 16b per oscillation period of the resonator element can be adjusted.

FIG. 2 shows an exemplary characteristic curve for a charge transfer according to a preferred embodiment of the invention. The time-averaged number <n> of transferred electrons per oscillation period is illustrated as a function of the applied voltage V. In this characteristic curve, if the electrical capacity or size of the charge transfer portion 18 is sufficiently small and if the temperatures are sufficiently small, steps in the form of plateaus and edges form due to the Coulomb blockade. The lower the temperatures, the stronger or sharper these steps are formed, i.e. the flatter the plateaus become and the steeper the edges become.

Preferably, the apparatus 10 is used as a current normal or current standard. To this end, if the charge transfer portion 18 is sufficiently small, i.e. if the electrical capacity of the charge transfer portion 18 is correspondingly small and if the operating temperature T is suitably low, the application of a suitable voltage V to the electrode elements 16 ensures that a fixed number of electrons, in particular one electron, is transferred with each oscillation period. Preferably, the voltage V is adjusted in the region of the centre of a plateau of the characteristic curve exemplarily shown in FIG. 2. The resulting current I=e·f is then given by the charge of the electron (elementary charge e) times the frequency f, with which the charge transfer portion 18 oscillates back and forth between the electrode elements 16. If the frequency f is precisely specified, a precisely specified current I results therefrom. By changing the voltage V between the electrode elements, one can change the number of electrons transferred by the charge transfer portion 18 per oscillation period. Depending on the number of electrons per oscillation period, the current is generally given according to I=n·e·f by the frequency f times the number n of the electrons per oscillation period times the elementary charge e.

The excitation of oscillation of the resonator element 12 is performed by means of the oscillation generator 20. In a preferred embodiment, the oscillation generator 20 generates a periodic, acoustic oscillation with at least one frequency component corresponding to a resonance frequency f₀ of the resonator element 12 or being at least close to such a resonance frequency. Thereby, the oscillation of the resonator element 12 is particularly efficiently excited. In another preferred embodiment, the oscillation generator 20 might generate a non-periodic, mechanical excitation, e.g. in the form of a one-time mechanical pulse, and thereby generate a continuum of acoustic oscillation frequencies as their Fourier components.

Preferably, the resonator element 12 comprises a material with low energy dissipation upon deformation, for example tensile stressed silicon nitride. This results in a high quality of the resonator element. The sharp resonance curve thus results in a precise specification of the resonance frequency. Preferably, an increase of tensile stress of the resonator element makes it possible to further improve the mechanical quality and thus the sharpness of the resonance frequency.

In a further preferred embodiment, the inventive apparatus is used as a high-precision frequency switch. A current flow or a maximum of the current flow between the electrode elements 16 occurs exactly when the oscillation generator 20 couples in an acoustic oscillation with sufficient amplitude, which contains one frequency component corresponding exactly to one resonance frequency f₀ of the resonator element 12. A high quality of the resonator element preferably results in the fact that already small excitation amplitudes are sufficient to excite an oscillation of the resonator element with a sufficient amplitude, which may be particularly advantageous at high frequencies if such frequencies can be generated or output less efficiently by the oscillation generator. Furthermore, low excitation amplitudes cause fewer heating of the system by the oscillation generator, which in turn preferably promotes the Coulomb blockade effect.

For this application, it is not even necessary for the number of electrons transferred per oscillation period to be precisely specified or known. A high selectivity or resolution for individual frequency components can be achieved by means of a high Q factor for the mechanical oscillation of the resonator element 12. If the excitation frequency of the oscillation generator 20 deviates only slightly from the resonance frequency f₀ of the resonator element, the amplitude of the oscillation of the resonator element, which is forced and excited by this excitation frequency, drops very quickly. Thereby, if the excitation amplitude is properly selected, the minimum distance of the charge transfer portion 18 from the individual electrode elements 16, which occurs during the oscillation, increases. Thereby, there is no more ohmic contact between the charge transfer portion 18 and the individual electrode elements, and/or when the minimum tunneling distance increases, the effective tunneling barrier increases and the tunneling probability, which in turn may represent a measure for the current, decreases exponentially. Preferably, a resonance curve of the electric current, which is clearly narrower as against the resonance curve of the mechanical oscillation, can thereby be achieved depending on the excitation frequency. Preferably, one thereby obtains a frequency switch or frequency filter with a particularly high frequency resolution or selectivity.

Preferably, the carrier substrate 14 has an electrically conductive layer as a gate layer. By application of an electrical voltage to the gate layer relative to the potential of the electrode elements 16, a slightly asymmetric fabrication of the electrode elements 16 and/or of the resonator element 12 can be compensated for in a particularly simple manner. In particular, during the oscillation process, an electric charge of the charge transfer portion 18, which is averaged for many oscillation periods and is different from zero, can be obtained thereby and thus leads to an effective force to one of the electrode elements in the electric field of the electrode elements 16 in order to compensate for a mechanical resilient force between the electrode elements 16, which is asymmetric to the centre.

FIG. 3 shows further preferred embodiments of an inventive charge transfer apparatus 10. The embodiment shown in FIG. 3A is constructed similar to the first embodiment, which is why reference is made to the description of FIG. 1 for corresponding details. Like elements are designated with the same reference numerals. According to the embodiment shown here, the oscillating portion 12c of the resonator element 12 comprises tuning elements 22, which at least partly oscillate together with the charge transfer portion 18 and contribute to the overall oscillation mass of the oscillating portion 12c. Depending on the size or mass of the tuning elements 22, the resonance frequency f₀ of the resonator element is influenced or specified. Furthermore, in this embodiment, the end portions 12a, 12b are formed with an enlarged diameter as against the oscillating portion 12c and form a resonator carrier structure each, which is in particular directly or indirectly connected with the carrier substrate 14 in a tight manner. With the thus achieved larger mechanical connection area with the carrier substrate 14, preferably the mechanical coupling to the acoustic oscillations and the transfer of a tensile stress in the resonator element are improved on the one hand, and the resonator element 12 can be produced in an particularly simple manner with a method described in the following with respect to FIG. 4 on the other hand.

FIG. 3B shows a perspective illustration of a charge transfer apparatus 10 according to a further preferred embodiment. In this embodiment, the resonator element 12 is arranged in its longitudinal direction substantially parallel to the substrate normal direction of the carrier substrate 14. The resonator element 12 is tightly fixed to the carrier substrate 14 only via one end portion 12a, while a second end facing away from carrier substrate 14 or extending upward from the carrier substrate 14 can oscillate and forms the oscillating portion 12c of the resonator element. Accordingly, the charge transfer portion 18 is arranged on the oscillating portion 12c formed by the free end of the resonator element 12. This free end and in particular the charge transfer portion 18 is movable between the two electrode elements 16a, 16b. Due to the elasticity of the resonator element 12 and the resilient force caused thereby, the oscillating portion has a rest position in which the charge transfer portion 18 is located between the two electrode elements 16a, 16b. By analogy with the described embodiments, the resonator element 12 preferably has at least one resonance frequency f₀ which is transferred or coupled into the resonator element 12 from the oscillation generator 20 via the end portion 12a in particular by means of the carrier substrate 14.

In this “vertical” arrangement of the resonator element 12 in the embodiment shown in FIG. 3B, a higher integration density in particular for a plurality of resonator elements is possible on the same carrier substrate due to the reduced lateral space requirement on the carrier substrate 14, which will be described in the following with reference to FIG. 8 and FIG. 9. For further details regarding the construction of the individual components and the operating principle as well as the use of the apparatus 10, the description in connection with the previous embodiments applies analogously. FIGS. 4A to 4J schematically illustrate individual intermediate steps of a production method of an inventive apparatus in a preferred embodiment. As is shown in FIG. 4A, the carrier substrate 14 is provided at first. As the carrier substrate, in particular a silicon substrate, e.g. in the form of a silicon wafer, could be used, for example. On this carrier substrate 14, a sacrificial layer 24, a resonator carrier layer 26, and a layer of a photoresist 28 are arranged successively or on top of each other. For example, the sacrificial layer comprises 400 nm of silicon dioxide, on which a silicon nitride layer with a thickness of approximately 100 nm is arranged as the resonator carrier layer 26.

As is shown in FIG. 4B, the photoresist 28 is lithographically structured e.g. by means of UV light or an electron beam. Thereby, electrode openings 30a, 30b and a charge transfer portion opening 32 for structuring of the future electrode elements 16a, 16b and the future charge transfer portion 18, respectively, are formed in the photoresist locally exposing the underlying resonator carrier layer 26. The charge transfer portion opening 32 is e.g. formed with a cross-section of approximately 100 nm×100 nm. Subsequently, as is shown in FIG. 4C, a metallization layer 34 is deposited e.g. by thermal vapour deposition. To this end, for example a gold layer with a thickness of approximately 10 nm to 100 nm and thereafter an aluminium layer with a thickness of approximately 30 nm are deposited in a successive manner. After a subsequent lift-off step, in which the structured photoresist 28 is removed together with the overlying metallization, the electrode elements 16a and 16b as well as the charge transfer portion 18 remain on the resonator carrier layer 26, as can be seen in FIG. 4D. The charge transfer portion 18 is in particular formed as an island having a size of approximately 100 nm×100 nm×100 nm.

Subsequently, as is shown in FIG. 4E, a further layer of photoresist 36 is deposited, which is lithographically structured forming an etching mask opening 38. In particular, the etching mask is formed substantially in the shape of the cross-section of the resonator element to be produced. As can be seen in FIG. 4F, an etching mask layer 40 is deposited thereon, which comprises e.g. aluminium. As is illustrated in FIG. 4G, an etching mask 42 remains on the resonator carrier layer 26 and the charge transfer portion 18 after a further lift-off step.

The resonator element is formed preferably in two etching steps with the help of this etching mask 42. The first etching step preferably comprises an anisotropic, i.e. directed etching process (e.g. by means of CF₄ as etching gas). As is shown in FIG. 4H, etching into the layer structure is done substantially vertically, i.e. in the substrate normal direction, for example by reactive ion etching or a dry etching step, and thereby in particular the regions of the resonator carrier layer 26 and the sacrificial layer 24 not covered by the etching mask 42 or the electrode elements 16 are removed. In a subsequent isotropic etching process, for example a wet etching step using buffered hydrofluoric acid, the etching mask 42 and the, as described above, upper layer of the electrode elements 16a, 16b, which is e.g. made of aluminium, are removed completely and the sacrificial layer 24 partly. By selection of the correct etching duration, the sacrificial layer 24 below the oscillating portion 12c of the resonator element 12, which is formed as a beam or string, is preferably removed fully, while the sacrificial layer 24 below the end portions 12a, 12b formed with a larger cross-section remains at least partly and thus forms a tight connection of the resonator element 12 to the carrier substrate 14, as is illustrated in FIG. 4J.

FIG. 5 shows a further preferred embodiment of an inventive charge transfer apparatus 10. In this embodiment, the charge transfer apparatus comprises a shielding housing 44, which encloses the resonator element 12 or encloses it at least partly, and which is designed to shield electric and/or magnetic fields, in particular electromagnetic fields. To this end, the shielding housing preferably comprises an electrically conductive, in particular metallic material. A particularly trouble-free operation and consequently a high sensitivity and resolution of the apparatus can be achieved therewith. Particularly preferably, the oscillation generator 20 is arranged external to the shielding housing 44. Therewith, an electrical or magnetic or electromagnetic influencing of the charge transfer by means of the charge transfer portion 18 due to a possible electronic control of the oscillation generator 20 or other external fields is prevented or at least reduced. However, the acoustic oscillations can still be coupled in by the shielding housing 44, so that the charge transfer can be influenced or controlled via the acoustic oscillations of the oscillation generator 20.

Further preferred embodiments of a charge transfer apparatus 10 are illustrated partly schematically in FIGS. 6A to 6C. In these embodiments, the charge transfer apparatus 10 comprises a sensor electrode capacitively coupled to the charge transfer portion 18. As is shown in FIG. 6A and FIG. 6C, the sensor electrode 46 may be arranged on the carrier substrate 14. Thereby, the sensor electrode 46 remains substantially unmoved even upon oscillations of the resonator element 12. In the embodiment shown in FIG. 6B however, the sensor electrode 46 is at least partly arranged on the resonator element 12 and oscillates at least partly together with it. This ensures that the distance and thus the capacitive coupling of the sensor electrode 46 to the charge transfer portion 18 remains substantially constant also during the oscillations.

In particular, these preferred embodiments of the inventive apparatus can be particularly advantageously employed as charge sensors. Here, the voltage V on the electrode elements 16a, 16b is adjusted such that the current I in the apparatus is on one of the edges illustrated exemplarily in FIG. 2. Thus, the current responds very readily to a change of the electrical potential on the sensor electrode 46. A potential change can thereby be detected very readily. In particular, minor potential changes already lead to relatively large changes of the current I.

FIG. 7 shows a further preferred embodiment of a charge transfer apparatus 10 according to the present invention. FIG. 7A shows a schematic illustration and FIG. 7B a REM picture of the resonator element 12 with the sensor electrode 46 and a schematic connection. For better recognizability, the sensor electrode 46 has been contoured with a white line in the REM picture.

In this embodiment, the charge transfer apparatus 10 comprises a single electron transistor 48 (SET) with two contact electrodes 50a, 50b and a Coulomb blockade island 52 capacitively coupled to the sensor electrode 46. The single electron transistor 48 is particularly suitable for a high-resolution detection of a potential change on the sensor electrode 46 even in the case of very fast potential changes. For example, in particular the conductivity of the single electron resistor 48 changes very readily and quickly upon a change of the electrical potential of the sensor electrode 46, which in turn functions as a sensor for a change of the electrical potential of the charge transfer portion 18 capacitively coupled to the sensor electrode 46. Thereby, the charge state of the charge transfer portion 18 can be detected exactly to the electron and in a time-resolved manner.

Thus, in a preferred embodiment, an apparatus according to the present invention in particular in the embodiment with a single electron transistor 48 as a highly precise current counter or current detector or single electron counter in particular for a highly precise current calibration is used. With the single electron transistor 48, already small charges on the charge transfer portion 18 are detected with a very high time resolution. Thereby, it is possible to count electrons that are transported from one electrode element 16 to the other by the charge transfer portion 18 of the resonator element 12. This can be used for calibrating current meters exactly to the electron: If the current, which is transported by the resonator element 12 that is acoustically excited to oscillate, is measured by a high-sensitivity current meter over a specific integration period, this current can be determined exactly to the electron with the single electron transistor 48 and be matched to the current meter.

Since the read-out of a single electron transistor is possible done with alternating electric currents, it is possible that this generates alternating electric fields that influence or disturb the charge transfer by means of the resonator element 12. This is prevented or at least reduced by applying an electrical shielding layer to the single electron transistor 48 and its leads.

FIG. 8 and FIG. 9 illustrate further preferred embodiments of inventive apparatuses. In this embodiment, the charge transfer apparatus 10 comprises a plurality of resonance cells. Each of the resonance cells comprises two electrode elements 16a, 16b and a resonator element 12. As is shown in FIG. 8A and FIG. 8B, for example the first electrode elements 16a of the plurality of resonance cells are electrically connected to each other or are mutually contacted in an electrical manner. Likewise, the second electrode elements 16b of the plurality of resonance cells are electrically connected to each other or are mutually contacted in an electrical manner. Due to this parallel connection of many resonance cells, a higher overall current as a reference with at the same time high precision can be generated as a current normal for a use of the apparatus, for example.

As is shown in FIG. 8A, at least some of the resonator elements could exhibit substantially the same resonance frequency by being dimensioned substantially identically. This is particularly advantageous for the generation of higher currents by parallel connection, since all these resonator elements can then be excited at the same time with the same acoustic oscillation. On the other hand, in a preferred embodiment, at least some of the resonator elements 12 exhibit different resonance frequencies. As can be seen in FIG. 8A, this could be achieved by a different longitudinal extension of the oscillating portion 12c. Thereby, the apparatus 10 can for example be used to generate different currents depending on the coupled-in acoustic oscillation, since the overall current according to I=n·e·f depends on the frequency f.

In a further preferred embodiment, by analogy with the already described embodiments, in particular each resonator element 12 might be assigned a sensor electrode, or a sensor electrode might be formed in each resonance cell. In a particularly preferred embodiment, all sensor electrodes might be electrically connected to each other. In another particularly preferred embodiment, each sensor electrode is contacted individually, which enables an individual tuning of the individual resonance cells.

FIG. 9 shows sections of REM pictures of a preferred embodiment of an inventive apparatus similar to the apparatus of FIG. 8 with a plurality of resonance cells. FIG. 9A gives an overview of an entire resonance cell field, while FIG. 9A to FIG. 9C illustrate individual resonator elements from the resonance cell field in an enlarged manner. Unlike in the embodiment of FIG. 8A, the different resonance frequency of individual resonator elements 12 is obtained by the different number and mass of the tuning elements 22.

In a further preferred embodiment, an apparatus 10 is used for particularly low-noise measurements or as a particularly low-noise current-source or electron counter by at least some of the electrically conductive components, in particular one or more electrode elements 16 and/or one or more charge transfer portions 18 and/or one or more sensor electrodes 46 and/or one or more contact electrodes 50 of the single electron transistor 48 and/or one or more Coulomb blockade islands 52 comprising superconducting material.

Specifically, in a preferred embodiment, an inventive apparatus is used as a current source or current normal and/or as a potential or charge sensor and/or as a single electron counter and/or as a frequency switch by applying an inventive method in a preferred embodiment, as has been exemplarily described in connection with individual preferred embodiments. Preferably, individual features of the described embodiments can be combined such that different applications are possible at the same time or in succession. In another preferred embodiment, an apparatus is specialised by a suitable combination and dimensioning of the preferred elements for a desired application.

### LIST OF REFERENCE NUMERALS

10 charge transfer apparatus
12 resonator element
12a, 12b first, second end portion of the resonator element
12c oscillating portion
14 carrier substrate
16a, 16b first, second electrode element
18 charge transfer portion
20 oscillation generator
22 tuning element
24 sacrificial layer
26 resonator carrier layer
28 photoresist
30a, 30b electrode openings
32 charge transfer portion opening
34 metallization layer
36 photoresist
38 etching mask opening
40 etching mask layer
42 etching mask
44 shielding housing
46 sensor electrode
48 single electron transistor
50a, 50b contact electrodes
52 Coulomb blockade island

1. A charge transfer apparatus, comprising:
an oscillation generator configured to generate acoustic oscillations;
at least two electrode elements spaced apart from each other; and
a mechanical resonator element coupled to the oscillation generator and having at least one charge transfer portion movable between the two electrode elements.

2. The apparatus according to claim 1, wherein the charge transfer portion comprises an electrically conductive island arranged on an at least partly electrically insulating oscillating portion of the resonator element.

3. The apparatus according to claim 1, wherein the oscillation generator comprises a piezo actuator.

4. The apparatus according to claim 1, further comprising a carrier substrate via which the resonator element is configured to couple mechanically to the oscillation generator.

5. The apparatus according to claim 4, wherein the resonator element is fixed to the carrier substrate via a first end portion and a second end portion and is tensile stressed at least in an oscillating portion arranged between the two end portions.

6. The apparatus according to claim 4, wherein the resonator element is fixed to the carrier substrate via a first end portion, and a second end portion is movable between the two electrode elements when the resonator element is elastically deformed, and wherein the charge transfer portion is arranged on the second end portion.

7. The apparatus according to claim 1, further comprising a shielding housing configured to shield electric fields and/or magnetic fields, wherein the resonator element is arranged at least partly within the shielding housing.

8. The apparatus according to claim 7, wherein the oscillation generator is arranged at least partly external to the shielding housing.

9. The apparatus according to claim 1, wherein the at least one resonator element has a resonance frequency in the range between 10 kHz and 1 THz.

10. The apparatus according to claim 1, further comprising a sensor electrode configured to be capacitively coupled to the charge transfer portion.

11. The apparatus according to claim 10, further comprising a single electron transistor with a Coulomb blockade island, which is configured to be capacitively coupled to the sensor electrode, and contact electrodes configured to couple to the Coulomb blockade island via tunneling contacts.

12. The apparatus according to claim 4, further comprising a plurality of resonance cells arranged on the carrier substrate, each resonance cell comprising:
at least one first electrode element and one second electrode element spaced apart from the first electrode element; and
at least one mechanical resonator element coupled to the oscillation generator and having at least one charge transfer portion movable between the respective electrode elements.

13. The apparatus according to claim 12, wherein the first electrode elements of the plurality of resonance cells are coupled to each other in an electrically conductive manner, and wherein the second electrode elements of the plurality of resonance cells are coupled to each other in an electrically conductive manner.

14. The apparatus according to claim 12, wherein a plurality of the resonator elements of the plurality of resonance cells has different resonance frequencies.

15. The apparatus according to claim 12, wherein a plurality of the resonator elements has the same resonance frequency.

16. A method for transporting an electric charge, comprising:
applying an electrical voltage between two mutually spaced electrode elements; and
mechanically exciting at least one resonator element by means of acoustic oscillations such that a charge transfer portion comprised by the resonance element contacts the two electrode elements with at least one resonance frequency of the resonator element alternately in an electrical manner.

17. The method according to claim 16, wherein the resonator element is arranged on a carrier substrate, and the acoustic oscillations used to excite the resonator element are formed in the carrier substrate and/or are transmitted to the resonator element by the carrier substrate.

18. The method according to claim 16, wherein the step of mechanically exciting comprises generating an acoustic oscillation by means of a piezo actuator.

19. The method according to claim 16, further comprising:
capacitively coupling a sensor electrode to the charge transfer portion; and
detecting an electric current and/or a current change by the electrode elements.

20. The method according to claim 16, further comprising:
capacitively coupling a sensor electrode to the charge transfer portion; and
detecting an electrical potential and/or a potential change of the charge transfer portion by detecting an electrical potential or a potential change of the sensor electrode.

21. The method according to claim 20, wherein the step of detecting the electrical potential or the potential change of the sensor electrode comprises detecting an electrical conductivity or an electric current of a single electron transistor capacitively coupled to the sensor electrode.

22. A current source, comprising:
an oscillation generator configured to generate acoustic oscillations;
at least two electrode elements spaced apart from each other; and
a mechanical resonator element coupled to the oscillation generator and having at least one charge transfer portion movable between the two electrode elements,
wherein the current source employs the method according to claim 16.

23. The current source according to claim 22, wherein the method further comprises applying a direct voltage to the electrode elements such that on average, an integer number of electrons, in particular defined by the Coulomb blockade, in particular one electron per oscillation period of the resonator element, is from one electrode element to the other electrode element.

24. An electron counter, comprising:
an oscillation generator configured to generate acoustic oscillations;
at least two electrode elements spaced apart from each other; and
a mechanical resonator element coupled to the oscillation generator and having at least one charge transfer portion movable between the two electrode elements,
wherein the electron counter employs the method according to claim 20.

25. A potential sensor, comprising:
an oscillation generator configured to generate acoustic oscillations;
at least two electrode elements spaced apart from each other; and
a mechanical resonator element coupled to the oscillation generator and having at least one charge transfer portion movable between the two electrode elements,
wherein the potential sensor employs the method according to claim 16.

26. The potential sensor according to claim 25, wherein the method further comprises applying a direct voltage to the electrode elements such that on a time average, a half-integer number of electrons, in particular half an electron or 1.5 electrons per oscillation period of the resonator element, is from one electrode element to the other electrode element.

27. The apparatus according to claim 1, wherein the at least one resonator element has a resonance frequency in the range greater than 0.1 MHz and/or smaller than 1 GHz.

28. The apparatus according to claim 1, wherein the at least one resonator element has a resonance frequency in a range of more than 1 MHz and/or less than 100 MHz.
